(19) United States
(12) Patent Application Publication
(10) Pub. No.: US 2003/0062597 A1
(43) Pub. Date: Apr. 3, 2003

(54) Switching device

(76) Inventors: Koenraad Rutgers, Keysoe (GB); Stephen Wilton Byatt, Bromham (GB)

Correspondence Address: KLEIN, O'NEILL & SINGH, Suite 510, 2 Park Plaza, Irvine, CA, 92614, US

(21) Appl. No.: 10/255,202

(22) Filed: Sep. 26, 2002

(30) Foreign Application Priority Data
Sep. 28, 2001 (GB) GB 0123323.8

(51) Int. Cl. H01L 29/00

(52) U.S. Cl. 257/557

(57) ABSTRACT

A PNPN semiconductor switching device for igniter circuits comprises first and third diffusion layers of N-type conductivity semiconductor material, second and fourth diffusion layers of P-type conductivity type semiconductor material, and a first buried region of N-type conductivity in the third layer adjacent to the junction between the second and third layers. The buried region has a greater impurity concentration than the third layer and serves to control the switching voltage of the device The first to third diffusion layers form an NPN transistor and a resistance is formed as part of the transistor base diffusion between the base and emitter diffusion regions of the transistor for controlling the switching current of the device.

The present invention relates to a switching device for a spark generator circuit.

Bi-directional silicon switching devices are often used in spark or pulse generator circuits, for example, igniting gas appliances or lamp ignition

In a typical circuit mains voltage is used to charge a capacitor. When the breakover voltage of the silicon switching device is exceeded the device triggers into conduction and the capacitor is discharged through a primary of a step up transformer. The transformer generates a much higher voltage across its secondary winding which then produces a spark across a spark gap. This spark can then be used to ignite a gas appliance.

Such circuits can also be used to generate the high voltages required to strike gas discharge tube lamps In the case of HID lamps the circuit is required to provide multiple, e.g. at least three ignition pulses for each mains half cycle. A very narrow voltage window is required on the switching device in order to guarantee that all ballasts meet this requirement during production of the circuits.

The switching device used is typically a four layer PNPN device and the switching voltage characteristics of the PNPN device must be closely controlled to give reliable operation with variations in mains voltage. If the breakdown voltage of the device is too low, there will not be enough energy stored in the capacitor to provide an adequate spark. If the breakdown voltage is too high then this will prevent the device from triggering. In addition the triggering current must be controlled so that there is enough current to trigger the semiconductor device but the current should not be so low that the device stays switched on after discharging the capacitor.

A simple glass passivated PNPN device is generally used for the switching device but it is difficult to manufacture such a device with the required electrical tolerances.

Accordingly, the present invention provides a PNPN semiconductor switching device for igniter circuits comprising first and third diffusion layers of a first conductivity semiconductor material; second and fourth diffusion layers of a second conductivity type semiconductor material, and a first buried region of the first conductivity type in the third layer adjacent to the junction between the second and third layers, the buried region having a greater impurity concentration than the third layer, wherein said buried region serves to control the switching voltage of the device; said diffusion layers form a transistor, and a resistance is formed between the base and emitter diffusion regions of the transistor for controlling the switching current of the device.

Advantageously, said transistor is an NPN transistor, said second layer forms said transistor base region and said first layer forms said emitter region and said resistance is formed as part of the base diffusion of said transistor.

In a preferred form of the invention said first layer is a highly doped N⁺ type emitter region, said second layer is a P-type base region, said third layer is an N-type substrate, said fourth layer is a P-type deep anode region and said buried region is an N-type diffusion region.

A further form of the invention has a PN diode connected in anti-parallel with said PNPN device.

Advantageously, said PN diode and said PNPN device are fabricated as a monolithic integrated circuit, and said diode has a deep anode diffusion in opposition to an N-type diffusion region.

Preferably, said resistance connects the base region of the PNPN device with the anode of the anti-parallel diode

In a further preferred form of the invention two such PNPN devices are connected in anti-parallel with one another to form a bi-directional switching device. A respective resistance is formed between the base and emitter diffusion regions of the transistor of each said PNPN device for controlling the switching current of each said PNPN device, and each said resistance collects the base region of a respective one of said PNPN devices with the anode of the other of said PNPN devices The compound device is advantageously fabricated as a monolithic integrated circuit.

The present invention is further described hereinafter, by way of example, with reference to the accompanying drawings, in which.

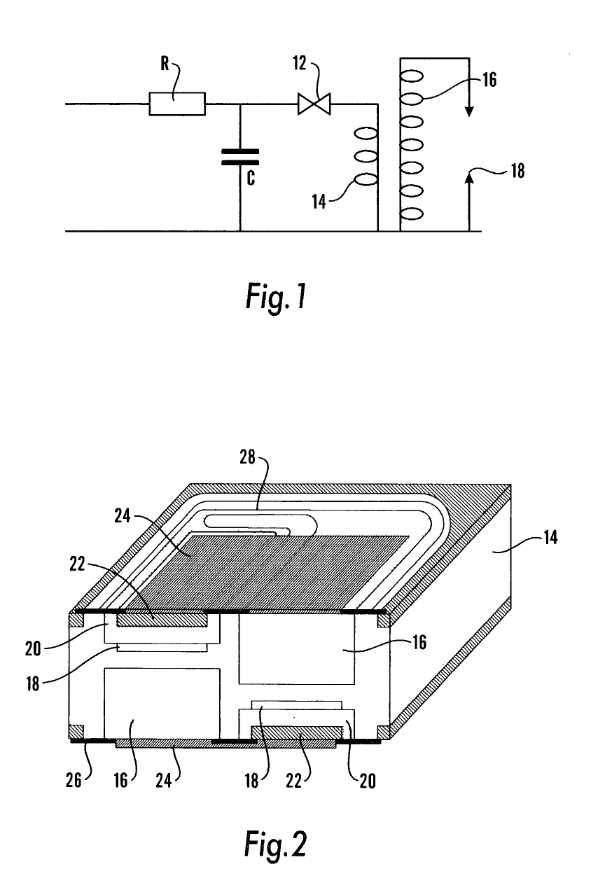

FIG. 1 is a circuit diagram of a typical spark generator circuit;

FIG. 2 is a cross-section through a preferred form of semiconductor switching device according to the present invention;

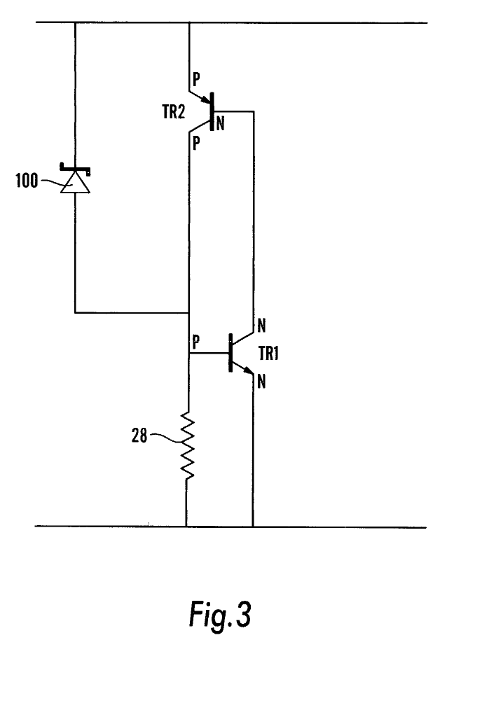

FIG. 3 is an equivalent circuit of one half of the device of FIG. 2;

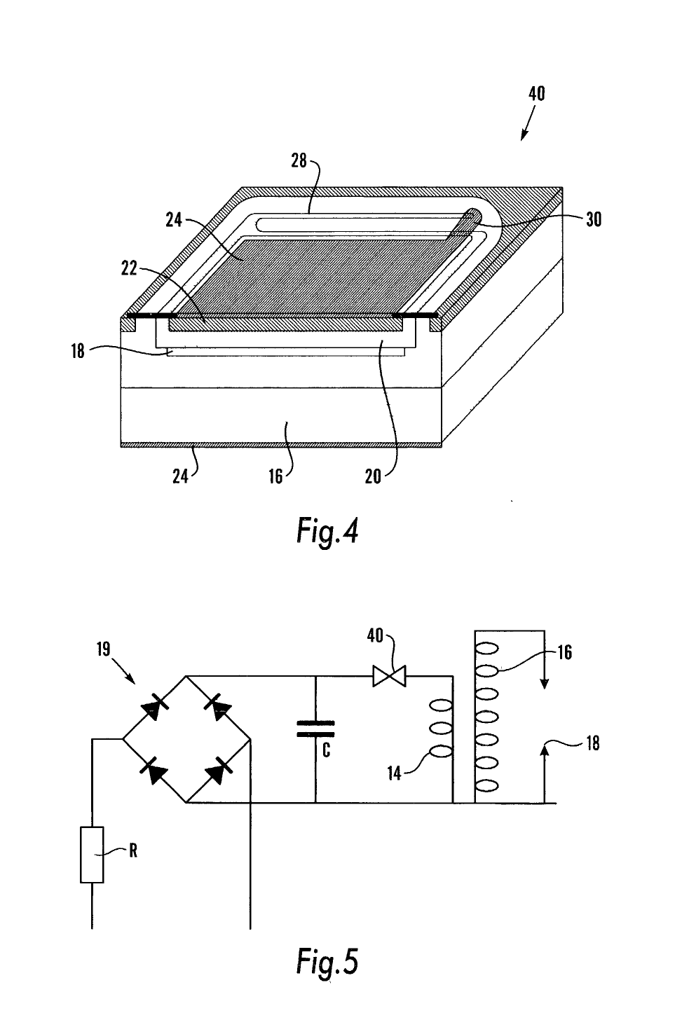

FIG. 4 is a view similar to that of FIG. 1 of a second form of switching device according to the present invention;

FIG. 5 is a circuit diagram similar to that of FIG. 1 using the device of FIG. 4;

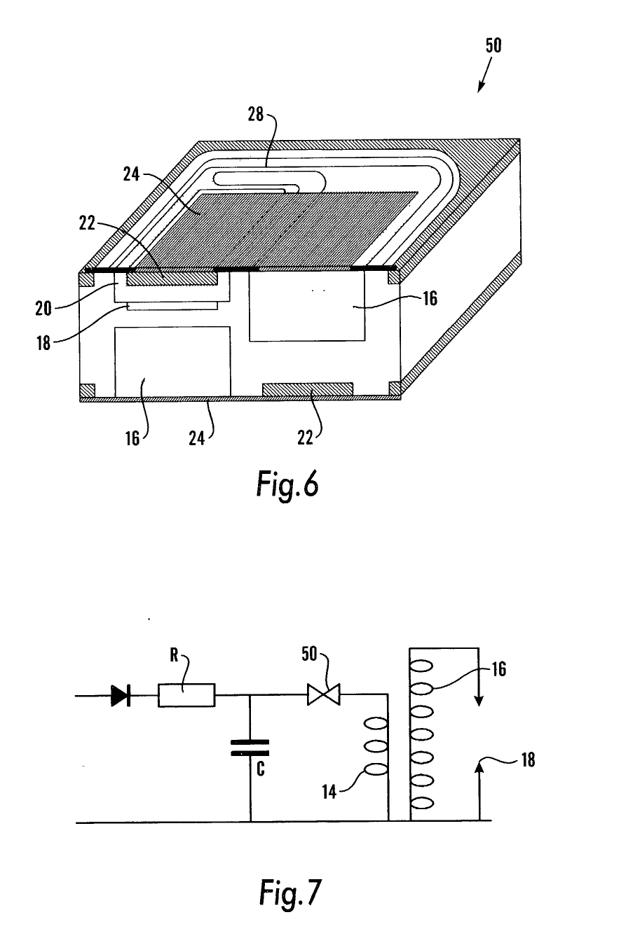

FIG. 6 is a view similar to that of FIG. 2 of a third form of switching device according to the present invention;

FIG. 7 is a circuit diagram similar to that of FIG. 1 showing a circuit for using the device of FIG. 6, and

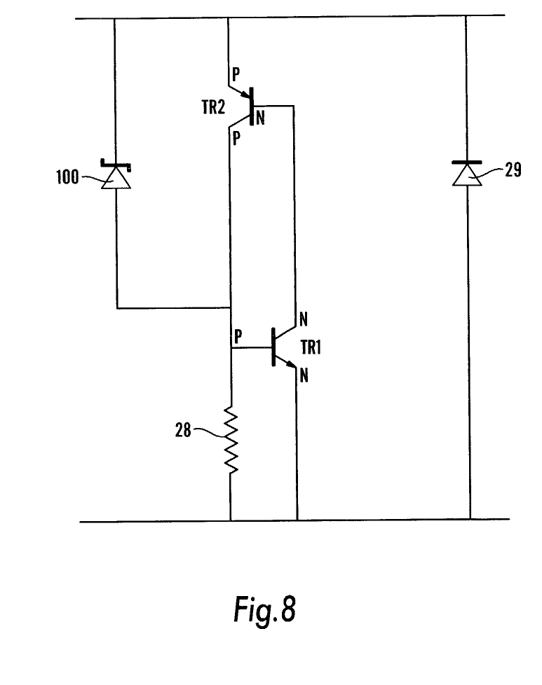

FIG. 8 is an equivalent circuit of one half of the device of FIG. 6

Referring to FIG. 1 this shows a simple spark generator circuit 10 in which a capacitor C is charged by mains voltage through a resistor R. The circuit has a PNPN bi-directional semiconductor switching device 12 which is triggered into conduction when the voltage across the capacitor C exceeds the breakover voltage of the device 12. This discharges the capacitor through a primary winding 14 of a step up transformer. The transformer generates a much higher voltage across its secondary winding 16 which produces a spark across a spark gap 18

Referring now to FIG. 2, this shows a cross-section through a preferred embodiment of semiconductor switching device 12 according to the present invention which would be used in the circuit of FIG. 1

The device shown in FIG. 2 is a bi-directional PNPN device which has a N-type substrate 14. P-type deep anode regions 16 are formed on opposite sides of the N-type substrate by diffusion. A more highly doped N-type diffusion 18 is then introduced into the substrate 14 on each side of the substrate directly opposite each deep anode region 16 The P-type base regions 20 and highly doped N⁺ type emitter regions 22 are then diffused into the substrate. Finally, metal and oxide layers 24, 26 are deposited, the metal layers forming the contacts of the device.

As can be seen from FIG. 2, the device consists of two PNPN structures in anti-parallel. The N diffusion 18 beneath the base diffusion 20 of each structure allows the switching voltage of the device to be accurately set during manufacture. A switching voltage of about 200 V is suitable for most ignitor circuits.

The regions 22 and 20 form the emitter and base regions of an NPN transistor whilst the regions 18 and 14 form the collector region

In addition, a diffused resistance 28 is formed during diffusion of the base 20 and this resistance 28 links the anode 16 of one of the PNPN structures and the emitter 22 of the NPN transistor of the adjacent PNPN structure to the base 20 of the adjacent PNPN structure. The resistance 28 controls the switching current of the device. In practice, the resistance 28 has a value of several thousand ohms to give a well controlled switching current of a few hundred microamps.

The capacitor of the circuit of FIG. 1 can be charged in both negative and positive directions of the mains voltage cycle and since the device shown in FIG. 2 can switch in both pluralities the circuit is suitable for generating multiple pulses for each mains cycle.

The N-type diffusions 18 set the breakover voltage V_{BO}.

By including the controlled voltage breakdown region and the well defined resistance 28 in the PNPN device, a bi-directional switch can be made with the required tolerances for ignitor circuits.

FIG. 3 is an equivalent circuit of one of the PNPN structures of FIG. 2. The transistor TR1 is formed by the emitter region 22, base region 20 and collector regions 14 and 18 of the structure of FIG. 2 Transistor TR2 is formed by the emitter region 16, base region 14 and collector region 20 of the structure of FIG. 2. The voltage across the device is applied across the breakdown diode 100 and the resistance 28. The breakdown diode 100 is formed by the base diffusion 20 and the N-type diffusion 18. Once the voltage across the diode 100 exceeds the breakover voltage the diode begins to conduct but the resistance 28 controls the switching current through the diode 100 As the current through the resistance 28 increases it turns on the first transistor TR1 which in turn turns on the second transistor TR2

Referring to FIG. 4 this is a view similar to that of FIG. 2 but showing a uni-directional switching device 40 As can be seen the structure is basically identical to the left hand side of FIG. 2 Parts of the device 40 which are similar to those of the device 12 are given like reference numbers. The equivalent circuit for the structure of FIG. 4 is the same as is shown in FIG. 3.

In the structure of FIG. 4 the diffused resistance 28 is formed as part of the base diffusion 20 and is connected to the emitter of the device by an extension 30 of the upper metal layer 24

The device of FIG. 4 would be used, for example, in a circuit such as that shown in FIG. 5. This is similar to the circuit of FIG. 1 and like parts are given like reference numbers. However, the charging of the capacitor C is effected through a bridge rectifier 19. As a result, the device 12 is only required to switch in one direction. An anti-parallel diode is not required in the structure of FIG. 4 because the bridge rectifier 19 provides a return current path.

FIG. 6 is a view, similar to that of FIG. 2, showing a switching device 50 having an asymmetrical structure. Again, those parts which are similar to those of FIG. 2 are given the same reference numbers

In the device of FIG. 6 the structure in the left hand portion is identical to the left hand portion of FIG. 2 However, the right hand structure forms an anti-parallel diode 29 and has a deep anode diffusion 16 in opposition to a highly doped N⁺-type diffusion region 22. The diffused resistance 28 connects the base 20 of the left-hand PNPN structure with the emitter region 22 and also the deep anode 16 of the right hand structure

The equivalent circuit for the device of FIG. 6 is shown in FIG. 8.

The device of FIG. 6 would be used in a circuit such as that shown, for example, in FIG. 7. This circuit is similar to that of FIG. 1 and again like parts are given like reference numbers.

In FIG. 7 since the capacitor C is only charged in one direction (one plurality) the device 12 of FIG. 5 is only required to switch in one direction. The anti-parallel diode 29 provides the oscillatory return path for the current which helps to recharge the capacitor. This circuit is suitable for lower switching rates such as are used in gas ignitors.

1 A PNPN semiconductor switching device for igniter circuits comprising.
first and third diffusion layers of a first conductivity semiconductor material;
second and fourth diffusion layers of a second conductivity type semiconductor material;
and a first buried region of the first conductivity type in the third layer adjacent to the junction between the second and third layers, the buried region having a greater impurity concentration than the third layer;
wherein
said buried region serves to control the switching voltage of the device;
said diffusion layers form a transistor,
and a resistance is formed between the base and emitter diffusion regions of the transistor for controlling the switching current of the device.

2 A device as claimed in claim 1 wherein said transistor is an NPN transistor.

3. A device as claimed in claim 1 wherein said second layer forms said transistor base region and said first layer forms said emitter region

4. A device as claimed in claim 1 wherein said resistance is formed as part of the base diffusion of said transistor.

5 A device as claimed claim 1 wherein said first layer is a highly doped N⁺ type emitter region, said second layer is a P-type base region, said third layer is an N-type substrate, said fourth layer is a P-type deep anode region and said buried region is an N-type diffusion region.

6 A compound PNPN device including a PNPN device as claimed in claim 1 and a PN diode connected in anti-parallel with said PNPN device

7 A compound device as claimed in claim 6 wherein said PN diode and said PNPN device are fabricated as a monolithic integrated circuit.

8. A compound device as claimed in claim 6 wherein said diode has a deep anode diffusion in opposition to an N-type diffusion region.

9 A compound device as claimed in claim 6 wherein said resistance connects the base region of the PNPN device with the anode of the anti-parallel diode.

10 A compound device comprising two PNPN devices as claimed in claim 1 and connected in anti-parallel with one another to form a bi-directional switching device;
wherein a respective resistance is formed between the base and emitter diffusion regions of the transistor of each said PNPN device for controlling the switching current of each said PNPN device,
and each said resistance connects the base region of a respective one of said PNPN devices with the anode of the other of said PNPN devices.

11 A compound device as claimed in claim 10 wherein said compound device is fabricated as a monolithic integrated circuit.
